(19) United States
(12) Patent Application Publication
(10) Pub. No.: US 2026/0126506 A1
(43) Pub. Date: May 7, 2026

(54) Implicit Field Estimator for Spatio-Temporally Varying Field Imperfections

(71) Applicant: The Board of Trustees of the Leland Stanford Junior University, Stanford, CA (US)

(72) Inventors: Zachary Andrew Shah, Stanford, CA (US); Daniel Raz Abraham, Palo Alto, CA (US); Kawin Setsompop, Stanford, CA (US)

(21) Appl. No.: 19/380,952

(22) Filed: Nov. 5, 2025

Related U.S. Application Data
(63) Continuation-in-part of application No. 19/200,007, filed on May 6, 2025.
(60) Provisional application No. 63/642,958, filed on May 6, 2024.

(51) Int. Cl. G01R 33/56; G01R 33/48; G01R 33/565

(52) U.S. Cl. CPC G01R 33/5608; G01R 33/4818; G01R 33/56563

(57) ABSTRACT

A method for magnetic resonance imaging acquires clean source data that is free of field imperfections, and target data that has field imperfections. The source data and target data are k-space data acquired under conditions of matching static B0 inhomogeneity and relaxation-based signal evolution in time. A neural network is trained using the source data and the target data to learn a mapping from temporal and gradient-based features to field GRAPPA-like kernels representing phase inhomogeneity effects. The kernels are used to reconstruct an image-domain phase inhomogeneity map which varies over time across a region of interest. An MRI image is then reconstructed using this extracted spatial-temporal phase imperfection to correct for field imperfection effects.

### CROSS-REFERENCE TO RELATED APPLICATIONS

This application is a continuation-in-part of U.S. patent application Ser. No. 19/200,007 filed May 6, 2025, which claims priority from U.S. Provisional Patent Application 63/642,958 filed May 6, 2024, both of which are incorporated herein by reference.

### STATEMENT OF FEDERALLY SPONSORED RESEARCH

This invention was made with Government support under contracts MH116173, EB033206, and EB019437 awarded by the National Institutes of Health. The Government has certain rights in the invention.

### FIELD OF THE INVENTION

The present invention relates generally to medical imaging. More specifically, it relates to methods for rapid magnetic resonance imaging techniques.

### BACKGROUND OF THE INVENTION

In magnetic resonance imaging (MRI), it is desirable to acquire images as fast as possible for a number of clinical reasons. However, such rapid imaging requires pushing the system to its limit, leading to system imperfections such as from eddy currents and gradient nonlinearities that can cause artifacts like blurring, distortion, and signal loss. Nuclear magnetic resonance (NMR) field probes can accurately measure these imperfections to achieve high-quality imaging, but these probes require additional hardware and cost.

### SUMMARY OF THE INVENTION

The present invention provides a data-driven approach to gradient field characterization. This enables enhanced image reconstruction for high-slew MRI without the need for external hardware, potentially revolutionizing fast acquisition MRI techniques and broadening their application.

The present invention provides methods, devices and systems for imaging-based approaches to estimate gradient imperfections by leveraging encoding capability of modern multi-channel receivers and neural networks for implicit Fourier phase representation.

MRI companies could use this invention to acquire and reconstruct scans with rapid acquisition sequences without requiring external hardware purchases or installation, permitting higher imaging quality for high slew-rate sequences.

To algorithmically estimate field imperfections, we acquire sets of measurements with different field imperfections. For example, a first set of scanner data is free of field imperfections (which we designate the source data), and a second set of scanner data has field imperfections present (which we call the target data). Then, for given sets of target and clean data, we find a time-dependent kernel that transforms of a set of points in the source data to the data in the target scan. Such a time-parameterized mapping is a Fourier-weighted multi-coil kernel which mimics the spatio-temporal field imperfection experienced during the target scan. Using this kernel and the spatial sensitivity maps of our receive coils, we can then extract the image-domain phase inhomogeneity across the region of interest using projections in a basis spanned by the multiple receive channels. This phase map can then be used in image reconstruction to correct for any field imperfection effects.

This method to estimate field imperfections algorithmically involves and efficient calibration scan, which uses an imaging sequence design that collects the source scanner data to which the target sequence desiring characterization can be referenced against. This method also involves a technique for field estimation, which uses a data-driven approach to retrieve the field inhomogeneity map from such scans at each timepoint along the scan.

The efficient calibration scan, which samples k-t space with a time-resolved imaging sequence. Examples include fully-phase encoded imaging, accelerated variants of echo-planar spectroscopic imaging (EPSI), and echo-planar time-resolved imaging (EPTI). For added efficiency, the target acquisition can be acquired at Fourier offsets to match nominally high-resolution trajectory data to a lower-resolution clean k-t dataset. For 3D characterization, a 2D acquisition can be performed at multiple slice positions to characterize cross-term interactions in orthogonal encoding axes, while only requiring an efficient collection of 2D k-space in the clean k-t dataset, instead viewed at multiple characterizing slice positions.

For characterizing system imperfections that are not subject-dependent, this calibration can be done a priori on a phantom before the subject enters the scanner. For scan prescriptions requiring subject-dependent gradient utilization, an efficient EPTI k-t sampling method presents a more efficient encoding from which a fully-sampled k-t space can be interpolated with minimal eddy currents at play in under one minute.

Field estimation algorithm. After the calibration scan has been completed, we collect the target scan along a desired trajectory, where this target scan matches to the B₀ inhomogeneity and relaxation-induced signal evolution of the calibration scan in time. Thus, any differences in the signals at the sampled k-t coordinates collected between the calibration and target scan are solely due to any system imperfections (such as concomitant fields and/or eddy currents), which we model as a time-evolving complex phase map which varies spatially over the field of view of the measured spins. If one knew this phase imperfection for every spatial position in the imaging plane at every time-point along the readout, they could reconstruct the image without the incurred distortion via a regularized least squares problem. We propose that a GRAPPA-like Fourier kernel can represent the phase imperfection at each timepoint, where a unique kernel describes the Fourier mapping of a collection of multi-channel points in the clean source data to a point along the target trajectory. For each coil and time point, given enough collected signal, we could solve for the kernel via least-squares; however, with few multi-channel signals collected per discrete timepoint, solving for the kernels via least squares would be heavily ill-posed. Instead, we exploit the smoothness and slow-evolving nature of the field over time to represent these kernels compactly by solving a stochastic optimization problem. With a machine learning approach, the collected data is applied to train a neural network which learns a mapping from temporal and gradient-based features to kernels representing the current phase inhomogeneity effects. Then, we reconstruct phase inhomogeneity maps from the set of kernels across each receive channel at a given time point, leveraging the multi-channel coil sensitivity maps to estimate the spatially varying gradient-induced phase off-resonance across image space.

Among other things, this technique uses multi-channel Fourier phase operators for the task of spatio-temporal field estimation. We provide a method to efficiently calculate an ensemble of spatio-temporal field operators using neural networks, where an ensemble of kernels are compactly represented in k-space. Phase imperfections are then reconstructed from these kernels by solving an eigenvalue system across the multiple receive coils.

### BRIEF DESCRIPTION OF THE DRAWINGS

FIG. 1A is a graph illustrating an accelerated EPSI-based reference calibration acquisition, an example sequence for the collection of a clean source dataset, according to an embodiment of the invention.

FIG. 1B is a graph illustrating a strategy to acquire the target dataset with gradient imperfections present collected at different Fourier offsets, according to an embodiment of the invention.

FIG. 2A is a diagram illustrating a k-t overlay of the acquired source and target calibration data, according to an embodiment of the invention.

FIG. 2B is a diagram illustrating gradient g, time t, and coordinate k for target trajectory as input with the phase kernel as the output of an MLP, with a visual depiction of the optimization problem solved, according to an embodiment of the invention.

FIG. 2C is a diagram illustrating the recovery of the phase of the spatial encoding imperfection from a trained MLP using coil sensitivity maps, according to an embodiment of the invention.

FIG. 3 is a diagram illustrating a simulation of acquired data used in method validation, according to an embodiment of the invention.

### DETAILED DESCRIPTION OF THE INVENTION

Gradient imperfections from eddy currents and trajectory error cause image artifacts. NMR field probes can accurately measure these imperfections to achieve high-quality imaging, but require additional hardware and cost. Here we present an imaging-based approach to estimate gradient imperfections by leverage encoding capability of modern multi-channel receivers and neural networks for implicit Fourier phase representation. The approach is adept for spiral-based imaging settings with eddy current, calibrated using low-gradient sequences without eddy effects present. Trained multi-layer perceptrons (MLPs) are used to compactly represent gradient phase imperfections in k-space as a function of time. The MLP estimates spatio-temporal phase to high accuracy, showing promise for high-order phase estimation without NMR field probes.

The present technique provides an imaging-based approach as an alternative to spatially higher-order gradient encoding field characterization using field probes. This enables enhanced image reconstruction for high-slew MRI without external hardware, potentially revolutionizing fast acquisition MRI techniques and broadening their application.

Spiral and echo-planar imaging have grown in popularity due to their ability to more fully utilize the limits of the gradient systems for fast acquisition. However, the necessarily high slew rates introduce gradient imperfections, such as eddy currents and trajectory errors. Since gradient distortions are a function of only the imaging sequence and MRI system, mitigation attempts often involve a calibration scan for gradient characterization, modeling phase to limited spatial order to compensate distortion effects when used during reconstruction. One-dimensional gradient estimates can be done without the need for additional hardware by backing out phase effects using a self-encoded slice selection algorithm. Inclusion of higher-order terms into the phase characterization using a set of NMR field probes with high temporal resolution has been shown to further improve image reconstruction. However, this comes at a price of additional hardware that could add cost and complexity; additionally, these phase estimates are limited to 3rd order spherical harmonics.

Techniques that rely on learned correlations in k-space from multichannel receiver training data have been successful in performing k-space interpolation to fill missing k-space data (GRAPPA, SPIRIT), moving non-cartesian data onto a cartesian grid to facilitate faster reconstruction (GROG), as well as estimating coil sensitivity information (ESPRIT). Recently the use of a simple neural network via a multi-layer perceptron (MLP) has been proposed to create an implicit representation of such multi-channel k-space correlation relationship and shown to improve the performance of GROG.

The present technique exploits multi-channel k-space correlation for use in characterizing gradient imperfections though a data driven approach: implicit Field Estimators for Spatio-Temporally Varying Eddy currents (FESTIVE). This can be performed through a calibration scan without the need for external hardware, relying only on the parallel receive coils as probes for gradient characterization. Additionally, this data-driven approach provides more flexibility to estimate higher-order terms beyond the constraint of third-order spherical fitting.

We first describe a model of the system. We typically design a gradient waveform to produce a trajectory k(t) in order to sample k-space efficiently, where signal s_{c}(t) from the c-th coil with sensitivity map S_{c}(r) is given by

$${s}_{c} ( t ) = {\int }_{r} {S}_{c} ( r ) m ( r ) {e}^{j 2 π {k ( t )}^{T} r} dr$$

where m(r) is the tissue magnetic moment at location r.

For high-slew systems, we can model the induced eddy current effects by including an additional phase term, as follows:

$${\tilde{s}}_{c} ( t ) = {\int }_{r} {S}_{c} ( r ) m ( r ) {e}^{j 2 π {k ( t )}^{T} r} {e}^{j {ϕ}_{c} ( r , t )} dr$$

This phase φ_{c}(r,t) is generally smooth both spatially and temporally, as the strength of eddy currents induced by a single gradient switching will decay exponentially with time. We propose an approximation to the true phase using a sum of K weighted Fourier harmonics. With decomposition onto the set of sensitivity coils in our parallel receive system, the phase model becomes:

$${e}^{j {ϕ}_{c} ( r , t )} = {\sum }_{k = 1}^{K} {\sum }_{c = 1}^{C} {S}_{c} ( r ) {w}_{k , c} ( t ) {e}^{j 2 π {k}_{k}^{T} r}$$

With this description, we can relate the true signal \tilde{s}_{c} (t) to data acquired without eddy currents. First, to simplify the problem, we apply a change of basis to the coils onto the left singular vectors u_{j,i} of the coil subspace:

$${\hat{S}}_{i} = {\sum }_{j = 1}^{C} {u}_{j , i} {S}_{j}$$

We project the received signal onto the first basis coil \tilde{S}₁, which is relatively flat in both magnitude and phase:

$$\begin{matrix}{\tilde{s}}_{1} ( t ) & = {\int }_{r} {\hat{S}}_{1} ( r ) m ( r ) {e}^{j 2 π {k ( t )}^{T} r} {\sum }_{k = 1}^{K} {\sum }_{c = 1}^{C} {\hat{S}}_{c} ( r ) {w}_{k , c} ( t ) {e}^{j 2 π {k}_{k}^{T} r} dr \\ & = {\sum }_{k = 1}^{K} {\sum }_{c = 1}^{C} {w}_{k , c} ( t ) {\int }_{r} {\hat{S}}_{1} ( r ) {\hat{S}}_{c} ( r ) m ( r ) {e}^{j 2 π {( k ( t ) + {k}_{k} )}^{T} r} dr \\ & = {\sum }_{k = 1}^{K} {\sum }_{c = 1}^{C} {\hat{w}}_{k , c} ( t ) {s}_{c}^{k} ( t )\end{matrix}$$

Here, each

$${s}_{c}^{k} ( t )$$

term is the clean data unset from \tilde{s}_{c}(t) by the spatial frequency k, and ŵ_{k,c} are the Fourier weights relative to the first coil Ŝ₁ (r). In other words, the application of a spatio-temporal phase on our signal can be modeled as a convolution with a grid of points surrounding the original data. Writing this system compactly, we can state that r(t)=G(t) ⊙\vec{s}(t) for r(t)=\tilde{s}₁(t) as our “target” data along the high-gradient trajectory, and s (t) as the collection of clean data, which we denote the “source” points.

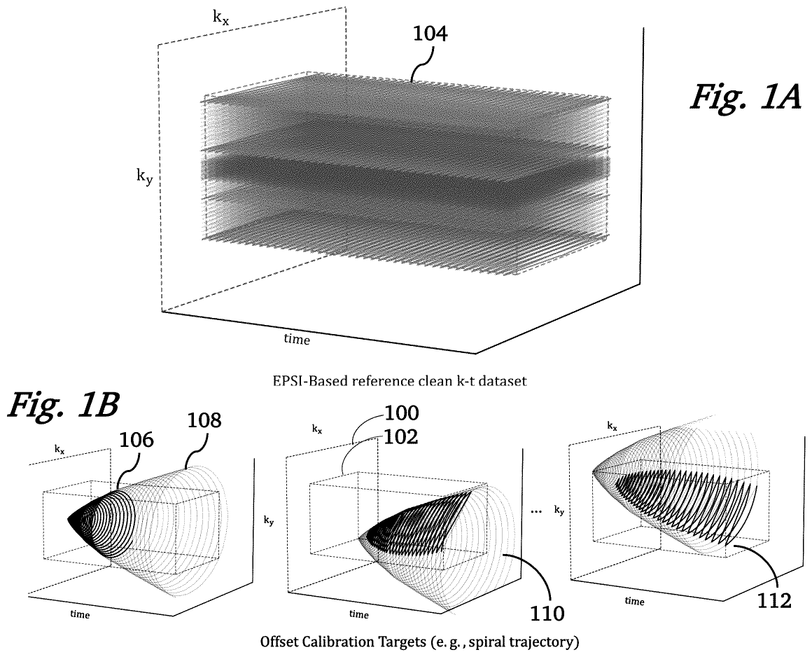

The source data can be collected using sequences designed to cover k-t space with low slew rates as shown by example in FIGS. 1A, 1B which are graphs of data acquisition trajectories. FESTIVE uses this sampling of the k-t space to form reference measurements for a target trajectory with minimal gradient imperfections. This can be collected naively by playing low-slew prewinders to each (kₓ, k_{y}) position and reading signal without gradient encoding. With short TR (70 ms), 22 cm FOV, and 1.5 mm resolution, this takes 20 minutes. For high resolution target extents as in 100, A more efficient k-t sampling method is echo-planar spectroscopic imaging (EPSI) (as shown in FIG. 1A), bringing the reference scan time down to under a minute with GRAPPA-based k_{y} acceleration outside a fully-sampled low-resolution extent 102. Each line of the EPSI 104 can be collected with dual polarity readouts to minimize odd/even phase errors. Collecting this source scan at potentially a lower acceleration than the target, we then collect a full-resolution target trajectory 108 (as shown in FIG. 1B) to perform FESTIVE's multi-coil modeling on k-t locations 106 overlapping with the source dataset counterpart (as shown in FIG. 1B). Higher resolution parts of the target trajectory can be sampled with gradient imperfections at different (kₓ, k_{y}) shifts as in 110 and 112 to match to the source dataset. Source points are gridded at the Nyquist rate and can be kaiser-bessel interpolated to k-t positions surrounding each valid target.

The derived system is heavily underspecified; however, spatial and temporal smoothness of field variations implies that the G(t) kernels should reside in a low-dimensional space. Thus, we parameterize the set of kernels G(t) as learnable weights by a neural network f_{θ}(t). Signal data collected along k(t) becomes a set of j training points in the form (s^{(j)}, r^{(j)}, t₍ⱼ₎), in order to stochastically optimize the neural network weights. The eddy current phase can then be backed out directly from the kernels learned by the network.

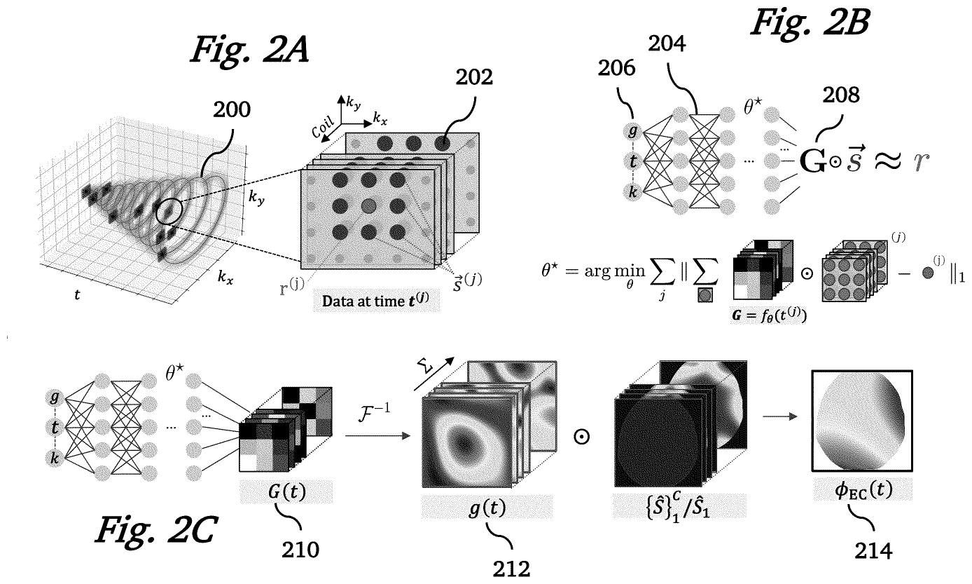

FIGS. 2A, 2B, 2C show the field estimation method. FIG. 2A shows the acquisition along a trajectory 200 of training data 202, with target with eddy currents r^{(j)}, and ground-truth interpolated source s^{(j)}. FIG. 2B illustrates how an MLP 204 takes in input features 206, such as time t, target gradient g and target trajectory coordinate k, as input, with the phase kernel 208 as the output. Kernel 208 maps the neighboring grid \vec{s}^{(j)} to the trajectory target r^{(j)}. This forms the objective minimized via stochastic optimization. FIG. 2C shows how the iFFT of optimized phase kernels G(t) 210 yields projections g (t) 212 onto each subspace coil relative to the primary coil. Hadamard multiplication and summation over coils yields the desired phase 214.

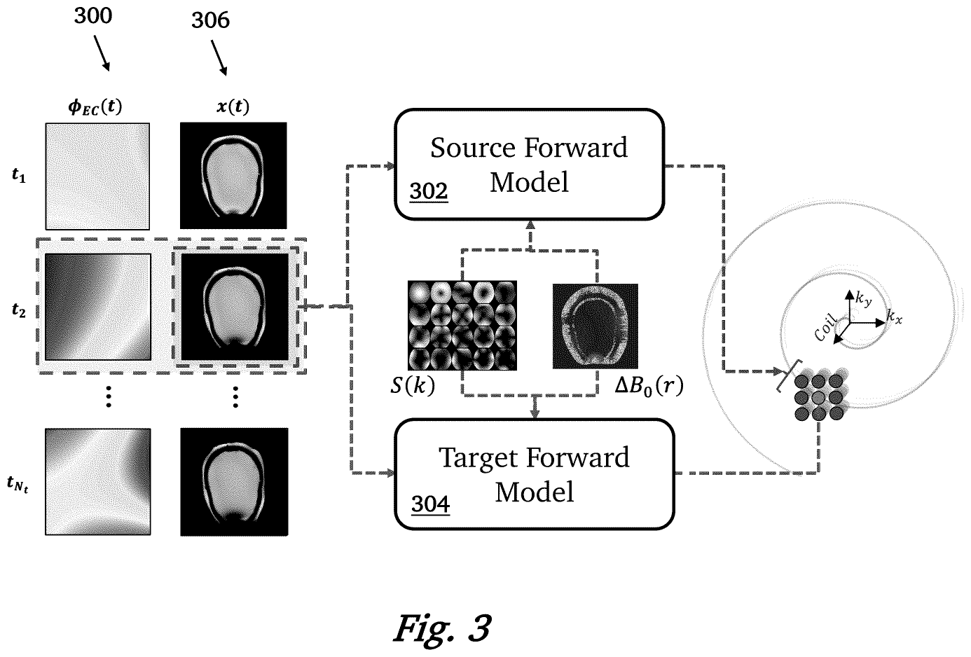

FIG. 3 shows a simulation of acquired data. Eddy current-induced phase φ_{EC} (t) 300 for a target spiral measured from field probes is temporally matched to imaged phantom x(t) 306 with T₂*(r) and PD maps, sampled every 2 μs. Phantom, coil maps, and B₀ map are passed into a forward model to produce source k-space data interpolated onto grid surrounding k(t) via Kaiser Bessel (Source Forward Model 302). Target point (Target Forward Model 304) simulated to center grid point with φ_{EC} (t) multiplied in image domain. Target forward model 304 generates data on k(t); Source forward model 302 generates data on grid centered at k(t).

We demonstrate the feasibility of an MLP to estimate gradient inhomogeneities with a simulation of the data acquisition process shown in FIG. 2A. For this, we imaged a phantom on a 3T scanner with 32 receive coils, with coil sensitivity maps estimated from an auto-calibration signal using ESPIRIT. We acquired a single-shot R=2 variable-density 2D spiral, and measured the gradient imperfections up to third order spherical harmonics using Skope NMR field probes. We then simulated signal acquisition, applying the Skope-measured fields as trajectory-induced gradient inhomogeneities, to generate source data r(t), simultaneously collecting the ground truth source points \vec{s}(t). Signal data was simulated per-timepoint to mimic the time-evolving effects of T₂*(r), ΔB₀(r), and the phase due to φ_{c} (r,t).

A shallow MLP then estimated the fields by mapping the spiral gradient waveform and time to a Fourier kernel representing the current phase. Training over 100 epochs with an Adam optimizer against an l1-loss on phase mapping error takes less than 30 seconds on a GPU. The estimated fields are then taken to be the coil-weighted Fourier-transformed kernels.

To characterize 3D phase interactions even for 2D acquisition trajectories, joint calibration is performed over several acquired imaging-slices to extract the 3D-spatiotemporal field-imperfection estimate.

1. A method for magnetic resonance imaging comprising:
a) acquiring data by an MRI scanner for calibrating gradient imperfections, wherein the data comprises a source dataset and a target dataset, wherein the source dataset and the target dataset are each acquired under conditions with different gradient imperfections but are matched in relaxation-based signal evolution and static B₀ inhomogeneity;
b) using the source dataset and the target dataset to learn a mapping from temporal-based and gradient-based features to Fourier-weighted multi-coil kernels representing phase inhomogeneity effects; wherein the Fourier-weighted multi-coil kernels are time-dependent and transform points in the source dataset to nearby points in the target dataset;
c) extracting a spatial-temporally-varying image-domain phase inhomogeneity across a region of interest using the Fourier-weighted multi-coil kernels and spatial sensitivity maps of receive coils;
d) reconstructing an MRI image from the target dataset using the extracted image-domain phase inhomogeneity to correct for field imperfection effects due to high slew rate acquisition sequences.

2. The method of claim 1 wherein the target dataset has field imperfections and the source dataset is free of the field imperfections.

3. The method of claim 1 wherein acquiring the source dataset and the target dataset by an MRI scanner comprises acquiring the target dataset by sampling k-t space along a target trajectory, and acquiring the source dataset comprises sampling k-t space surrounding the target trajectory.

4. The method of claim 1 wherein acquiring the source dataset comprises using a fully-phase encoded acquisition, an echo planar time resolved imaging acquisition, or an accelerated echo planar spectroscopic imaging acquisition for mapping imperfection-free k-space Nyquist-resolved in time.

5. The method in claim 1 wherein acquiring the target dataset is supplemented with target acquisitions at additional Fourier offsets to increase the fidelity of the calibration fit and allow lower-resolution k-t mapping of the source dataset.

6. The method of claim 1 wherein acquiring source dataset and target dataset by an MRI scanner comprises acquiring the source dataset in a calibration scan and subsequently acquiring the target dataset in a target scan, where the target scan matches a B₀ inhomogeneity and relaxation-induced signal evolution of the calibration scan in time.
